(19) United States
(12) Patent Application Publication
(10) Pub. No.: US 2025/0344328 A1
(43) Pub. Date: Nov. 6, 2025

(54) FOLDABLE DISPLAY DEVICE AND ELECTRONIC DEVICE INCLUDING THE SAME

(71) Applicant: Samsung Display Co., LTD., Yongin-si (KR)

(72) Inventors: MUNSIK HAM, Yongin-si (KR); HOSUNG NAM, Yongin-si (KR); HOSEUNG KANG, Yongin-si (KR); Hyunsu Sim, Yongin-si (KR)

(73) Assignee: Samsung Display Co., LTD., Yongin-si (KR)

(21) Appl. No.: 19/049,321

(22) Filed: Feb. 10, 2025

(30) Foreign Application Priority Data
May 3, 2024 (KR) 10-2024-0059096

(51) Int. Cl. H05K 5/02; H10K 59/80; H10K 102/00

(52) U.S. Cl. CPC H05K 5/0217; H10K 59/80; H10K 2102/311

(57) ABSTRACT

A foldable display device includes a support member divided into a folding area and at least one flat area adjacent to the folding area, at least one adhesive layer disposed on the support member, overlapping the at least one flat area, and including at least one corner adjacent to the folding area, and a display device disposed on the at least one adhesive layer. A radius of curvature is defined at the at least one corner.

### CROSS-REFERENCE TO RELATED APPLICATION(S)

This application claims priority to and benefits of Korean Patent Application No. 10-2024-0059096 under 35 U.S.C. § 119, filed on May 3, 2024 in the Korean Intellectual Property Office, the entire contents of which are incorporated herein by reference.

### BACKGROUND

### 1. Technical Field

Implementations of the disclosure relate generally to a display device and an electronic device including the display device. Implementations of the disclosure relate to a foldable display device capable of folding and unfolding.

### 2. Description of the Related Art

A display device is a device that displays an image and may include a display panel including display diodes such as organic light emitting diodes (OLED) and quantum dot electroluminescence diodes (QD-EL).

Mobile electronic devices include display devices to provide images to users. Recently, foldable display devices capable of folding and unfolding are being developed to provide a larger screen only in case that in use.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a foldable display device.

Embodiments provide an electronic device including the foldable display device.

A foldable display device according to an embodiment may include a support member divided into a folding area and at least one flat area adjacent to the folding area; at least one adhesive layer disposed on the support member, overlapping the at least one flat area, and including at least one corner having a radius of curvature, the at least one corner being adjacent to the folding area, and a display panel disposed on the at least one adhesive layer.

In an embodiment, the radius of curvature may be in a range of about 2 mm to about 4 mm.

In an embodiment, the at least one adhesive layer may include a first corner adjacent to the folding area and a second corner adjacent to the folding area and opposite to the first corner. The radius of curvature may be defined at each of the first corner and the second corner, and a shape of the second corner may be substantially symmetrical to a shape of the first corner.

In an embodiment, the at least one flat area may include a first flat area and a second flat area facing each other with the folding area disposed between the first flat area and the second flat area, the at least one adhesive layer may include a first adhesive layer overlapping the first flat area and a second adhesive layer overlapping the second flat area, and a shape of a corner included in the second adhesive layer may be substantially symmetrical to a shape of a corner included in the first adhesive layer.

In an embodiment, the at least one adhesive layer may further include a chamfer connected to the corner.

In an embodiment, the at least one adhesive layer may include a first corner adjacent to the folding area, a first chamfer connected to the first corner, a second corner adjacent to the folding area and opposite to the first corner, and a second chamfer connected to the second corner. The radius of curvature may be defined at each of the first corner and the second corner, a shape of the second corner may be substantially symmetrical to a shape of the first corner, and a shape of the second chamfer may be substantially symmetrical to a shape of the first chamfer.

In an embodiment, the at least one flat area may include a first flat area and a second flat area facing each other with the folding area disposed between the first flat area and the second flat area, the at least one adhesive layer may include a first adhesive layer overlapping the first flat area and a second adhesive layer overlapping the second flat area, a shape of a corner included in the second adhesive layer may be substantially symmetrical to a shape of a corner included in the first adhesive layer, and a shape of a chamfer included in the second adhesive layer may be substantially symmetrical to a shape of a chamfer included in the first adhesive layer.

In an embodiment, a maximum length from the corner to the chamfer may be in a range of about 4 mm to about 6 mm.

In an embodiment, a maximum width of the chamfer may be in a range of about 1 mm to about 3 mm.

In an embodiment, the at least one flat area may include a first flat area and a second flat area facing each other with the folding area disposed between the first flat area and the second flat area, the at least one adhesive layer may include a first adhesive layer overlapping the first flat area and a second adhesive layer overlapping the second flat area, the first adhesive layer may include the corner and the chamfer, and the second adhesive layer may include a corner with a defined radius of curvature.

In an embodiment, holes overlapping the folding area may be included in the support member.

In an embodiment, the foldable display device may further include a protective layer disposed between the at least one adhesive layer and the display panel and a panel adhesive layer disposed between the protective layer and the display panel, and overlapping the folding area and the at least one flat area.

In an embodiment, the at least one adhesive layer may not overlap the folding area.

In an embodiment, the display panel may include an active pattern disposed on a substrate, a gate electrode disposed on the active pattern, a connection electrode disposed on the gate electrode and electrically connected to the active pattern, a pixel electrode disposed on the connection electrode and electrically connected to the connection electrode, an emission layer disposed on the pixel electrode, and a common electrode disposed on the emission layer.

A foldable display device according to an embodiment may include a support member divided into a folding area and at least one flat area adjacent to the folding area; at least one adhesive layer disposed on the support member, overlapping the at least one flat area, and including at least one chamfer adjacent to the folding area, and a display panel disposed on the at least one adhesive layer.

In an embodiment, the at least one adhesive layer may include a first chamfer adjacent to the folding area and a second chamfer adjacent to the folding area and opposite to the first chamfer. A shape of the second chamfer may be substantially symmetrical to a shape of the first chamfer.

In an embodiment, the at least one flat area may include a first flat area and a second flat area facing each other with the folding area disposed between the first flat area and the second flat area, the at least one adhesive layer may include a first adhesive layer overlapping the first flat area and a second adhesive layer overlapping the second flat area, and a shape of a chamfer included in the second adhesive layer may be substantially symmetrical to a shape of a chamfer included in the first adhesive layer.

In an embodiment, a maximum width of the chamfer may be in a range of about 1 mm to about 3 mm.

An electronic device may include a foldable display device and a power supply that provides power to the foldable display device. The foldable display device according to an embodiment may include a support member divided into a folding area and at least one flat area adjacent to the folding area; at least one adhesive layer disposed on the support member, overlapping the at least one flat area, and including at least one corner having a radius of curvature, the at least one corner being adjacent to the folding area, and a display panel disposed on the at least one adhesive layer.

Therefore, a foldable display device according to embodiments may include a support member and an adhesive layer contacting the support member. The adhesive layer is removed from the folding area of the foldable display device, and at least one corner adjacent to the folding area may have a processed shape. For example, the adhesive layer may include a corner with a defined radius of curvature and a chamfer connected to the corner.

In case that the foldable display device falls and collides with the ground, stress applied to the adhesive layer adjacent to the folding area may be distributed. In detail, the stress may be distributed rather than concentrated due to the shape of the corner and the chamfer formed in the adhesive layer. Accordingly, the dropping performance of the foldable display device can be improved and reliability can be improved.

### BRIEF DESCRIPTION OF THE DRAWINGS

The accompanying drawings, which are included to provide a further understanding of the disclosure and are incorporated in and constitute a part of this specification, illustrate embodiments of the disclosure together with the description in which:

FIG. 1 is a schematic plan view illustrating a foldable display device according to an embodiment.

FIG. 2 is a schematic cross-sectional view illustrating a folded state of the foldable display device of FIG. 1.

FIG. 3 is a schematic cross-sectional view illustrating the foldable display device of FIG. 1.

FIG. 4 is a schematic cross-sectional view illustrating a display panel included in the foldable display device of FIG. 3.

FIG. 5 is a rear view illustrating the foldable display device of FIG. 1.

FIG. 6 is an enlarged view of area A of FIG. 5.

FIG. 7 is a diagram illustrating a falling foldable display device of FIG. 5.

FIG. 8 is a rear view illustrating a foldable display device according to an embodiment.

FIG. 9 is an enlarged view of area B of FIG. 8.

FIG. 10 is a rear view illustrating a foldable display device according to an embodiment.

FIG. 11 is an enlarged view of area C of FIG. 10.

FIG. 12 is a rear view illustrating a foldable display device according to an embodiment.

FIG. 13 is a block diagram illustrating an electronic device according to an embodiment.

### DETAILED DESCRIPTION OF THE EMBODIMENTS

Illustrative, non-limiting embodiments will be more clearly understood from the following detailed description in conjunction with the accompanying drawings.

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, sizes, thicknesses, ratios, and dimensions of the elements may be exaggerated for ease of description and for clarity. Like numbers refer to like elements throughout.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be understood that, although the terms first, second, etc., may be used herein to describe various elements, these elements should not be limited by these terms. These terms are only used to distinguish one element from another element. For example, a first element may be referred to as a second element, and similarly, a second element may be referred to as a first element without departing from the scope of the disclosure.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween.

It will be understood that the terms “connected to” or “coupled to” may include a physical or electrical connection or coupling.

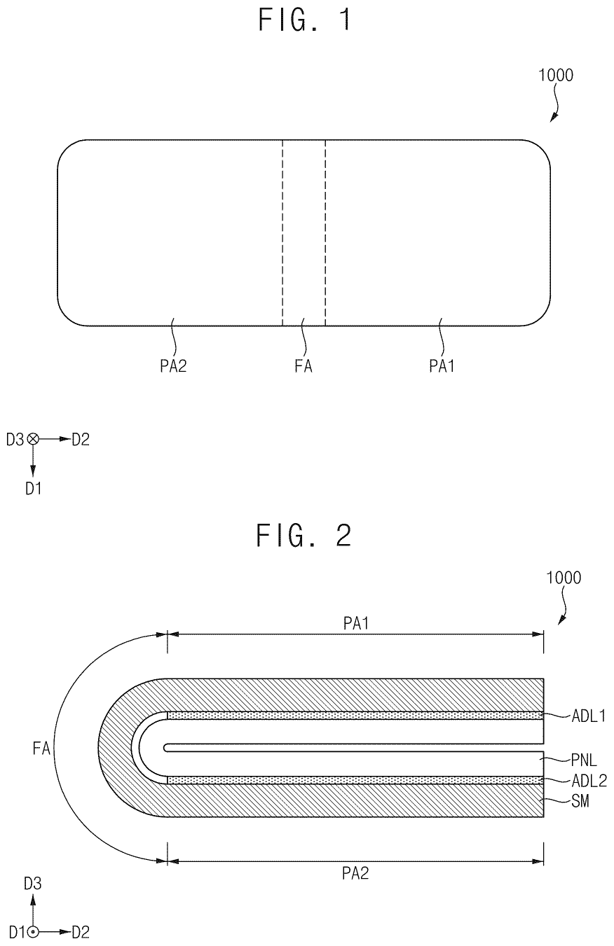

FIG. 1 is a schematic plan view illustrating a foldable display device according to an embodiment. FIG. 2 is a schematic cross-sectional view illustrating a folded state of the foldable display device of FIG. 1.

Referring to FIG. 1, the foldable display device 1000 according to an embodiment may be divided into a folding area FA, a first flat area PA1, and a second flat area PA2.

The foldable display device 1000 may have a display surface composed of a first direction D1 and a second direction D2 intersecting the first direction D1, and may have a thickness in a third direction D3 intersecting the first and second directions D1 and D2. The foldable display device 1000 may display images in the folding area FA, the first flat area PA1, and the second flat area PA2.

In an embodiment, the folding area FA may be located (or disposed) between the first flat area PA1 and the second flat area PA2. For example, the folding area FA may be adjacent to the second flat area PA2 in the second direction D2, and the first flat area PA1 may be adjacent to the folding area FA in the second direction D2.

Referring to FIG. 2, in an embodiment, the foldable display device 1000 may be folded and/or unfolded in the folding area FA. For example, as shown in FIG. 2, a display panel PNL and a support member SM included in the foldable display device 1000 may be folded in the folding area FA. A first adhesive layer ADL1 may be adhered to the support member SM in the first flat area PA1, and a second adhesive layer ADL2 may be adhered to the support member SM in the second flat area PA2.

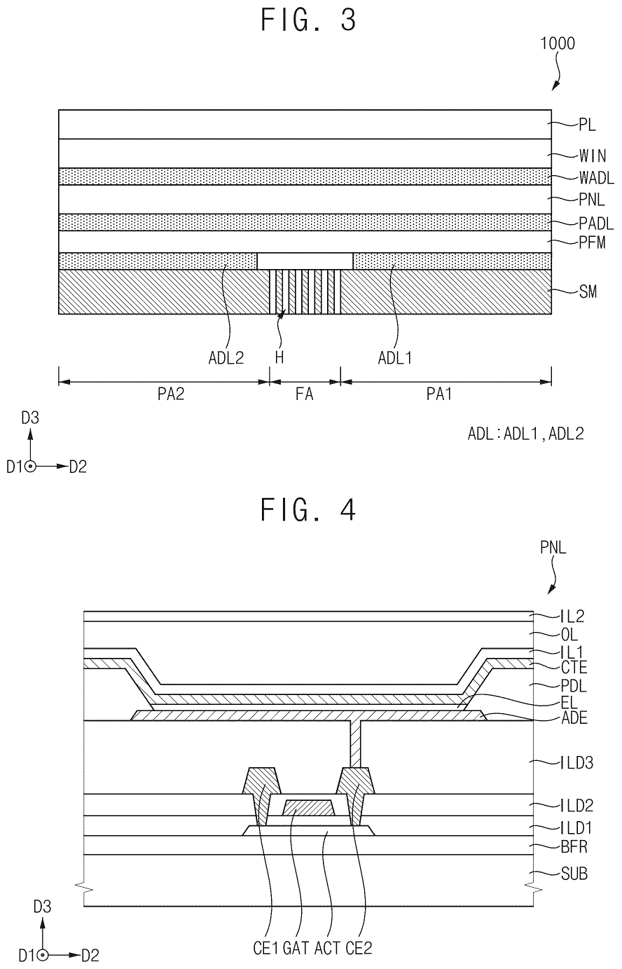

FIG. 3 is a schematic cross-sectional view illustrating the foldable display device of FIG. 1. FIG. 4 is a schematic cross-sectional view illustrating a display panel included in the foldable display device of FIG. 3.

Referring to FIG. 3, the foldable display device 1000 may include the support member SM, an adhesive layer ADL, a protective film (or layer) PFM, a panel adhesive layer PADL, the display panel PNL, a window adhesive layer WADL, a window WIN, and a window protection layer PL.

The support member SM may support the display panel PNL. In an embodiment, the support member SM may be formed of a material with high rigidity. For example, the support member SM may include invar which is an alloy of nickel (Ni) and iron (Fe), stainless steel (SUS), titanium (Ti), copper (Cu), etc.

In an embodiment, holes H overlapping the folding area FA may be defined in the support member SM. The holes H may penetrate the support member SM. Accordingly, the folding characteristics of the foldable display device 1000 may be improved.

In an embodiment, the adhesive layer ADL may include the first adhesive layer ADL1 and the second adhesive layer ADL2.

The first adhesive layer ADL1 may be disposed on the support member SM and may overlap the first flat area PA1. The first adhesive layer ADL1 may include an adhesive material such as pressure-sensitive adhesive (PSA), optically clear adhesive (OCA), or optically clear adhesive resin (OCR). The first adhesive layer ADL1 may contact the support member SM and may adhere the support member SM to the protective film PFM.

The second adhesive layer ADL2 may be disposed on the support member SM and may overlap the second flat area PA2. The second adhesive layer ADL2 may include an adhesive material such as pressure-sensitive adhesive (PSA), optically clear adhesive (OCA), or optically clear adhesive resin (OCR). The second adhesive layer ADL2 may contact the support member SM and may adhere the support member SM to the protective film PFM.

In an embodiment, the first adhesive layer ADL1 and the second adhesive layer ADL2 may not overlap the folding area FA. In other words, the adhesive layer ADL may be removed from the folding area FA. Accordingly, the folding characteristics of the foldable display device 1000 may be improved.

The protective film PFM may be disposed on the adhesive layer ADL. In an embodiment, the protective film PFM may be formed of plastic. The protective film PFM may support the display panel PNL and may absorb external shock.

In an embodiment, the foldable display device 1000 may further include a buffer member. For example, the buffer member may be disposed between the display panel PNL and the support member SM and may buffer external shock. The buffer member may include a material that contains air and can provide cushioning, such as a cushion or sponge. The buffer member may include acrylic resin, polyurethane, thermoplastic polyurethane, latex, polyurethane foam, polystyrene foam, etc.

The panel adhesive layer PADL may be disposed on the protective film PFM and may overlap the first flat area PA1, the second flat area PA2, and the folding area FA. The panel adhesive layer PADL may include an adhesive material such as pressure-sensitive adhesive (PSA), optically clear adhesive (OCA), or optically clear adhesive resin (OCR), and may adhere the display panel PNL to the protective film PFM.

The display panel PNL may be disposed on the panel adhesive layer PADL. The display panel PNL may overlap the first flat area PA1, the second flat area PA2, and the folding area FA, and may display an image.

Referring to FIG. 4, the display panel PNL may include a substrate SUB, a buffer layer BFR, an active pattern ACT, a first insulating layer ILD1, a gate electrode GAT, a second insulating layer ILD2, a first connection electrode CE1, a second connection electrode CE2, a third insulating layer ILD3, a pixel electrode ADE, an emission layer EL, a common electrode CTE, a pixel defining layer PDL, a first inorganic layer IL1, an organic layer OL, and a second inorganic layer IL2.

The substrate SUB may include glass, quartz, plastic, etc. For example, the substrate SUB may be a plastic substrate and may include polyimide (PI). In an embodiment, the substrate SUB may have a structure in which at least one polyimide layer and at least one barrier layer may be alternately stacked each other.

The buffer layer BFR may be disposed on the substrate SUB. The buffer layer BFR may include silicon oxide, silicon nitride, etc. The buffer layer BFR may prevent impurities from diffusing into the active pattern ACT.

The active pattern ACT may be disposed on the buffer layer BFR. For example, the active pattern ACT may include a silicon semiconductor, an oxide semiconductor, etc. The silicon semiconductor may include amorphous silicon, polycrystalline silicon, etc. The active pattern ACT may pass current or block current depending on the gate signal provided to the gate electrode GAT.

The first insulating layer ILD1 may include an insulating material and may cover the active pattern ACT. For example, the first insulating layer ILD1 may include silicon oxide, silicon nitride, titanium oxide, tantalum oxide, etc. The first insulating layer ILD1 may electrically insulate the active pattern ACT and the gate electrode GAT.

The gate electrode GAT may include a metal, alloy, conductive metal oxide, etc., and may be disposed on the first insulating layer ILD1. For example, the gate electrode GAT may include silver (Ag), an alloy containing silver, molybdenum (Mo), an alloy containing molybdenum, aluminum (Al), an alloy containing aluminum, aluminum nitride. (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), etc.

The second insulating layer ILD2 may include an insulating material and may cover the gate electrode GAT. For example, the second insulating layer ILD2 may include silicon oxide, silicon nitride, titanium oxide, tantalum oxide, etc. The second insulating layer ILD2 may electrically insulate the gate electrode GAT from the first connection electrode CE1 and may electrically insulate the gate electrode GAT from the second connection electrode CE2.

The first connection electrode CE1 and the second connection electrode CE2 may be disposed on the second insulating layer ILD2 and may be connected to the active pattern ACT.

In an embodiment, the first connection electrode CE1 and the second connection electrode CE2 may include metal, alloy, conductive metal oxide, etc. For example, the first and second connection electrodes CE1 and CE2 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), etc.

The third insulating layer ILD3 may cover the first and second connection electrodes CE1 and CE2, may include an organic insulating material, and may have a substantially flat top surface. For example, the third insulating layer ILD3 may include photoresist, polyacrylic resin, polyimide resin, acrylic resin, etc.

The pixel electrode ADE may be disposed on the third insulating layer ILD3 and may be connected to the second connection electrode CE2. The pixel electrode ADE may receive a first voltage from the second connection electrode CE2.

In an embodiment, the pixel electrode ADE may include metal, alloy, conductive metal oxide, etc. For example, the pixel electrode ADE may include silver (Ag), an alloy containing silver, molybdenum (Mo), an alloy containing molybdenum, aluminum (Al), an alloy containing aluminum, aluminum nitride. (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), etc.

The pixel defining layer PDL may be disposed on the third insulating layer ILD3, and an opening exposing the top surface of the pixel electrode ADE may be formed in the pixel defining layer PDL. For example, the pixel defining layer PDL may be made of organic materials such as polyimide resin (for example, photosensitive polyimide resin (PSPI)), photoresist, polyacrylic resin, and acrylic resin, or inorganic materials such as silicon oxide and silicon nitride.

The emission layer EL may be disposed on the pixel electrode ADE. In an embodiment, the emission layer EL may have a multilayer structure including an organic light emitting layer, a hole injection layer, a hole transport layer, an electron transport layer, and an electron injection layer.

The common electrode CTE may be disposed on the emission layer EL and may provide a second voltage. The common electrode CTE may include metal, alloy, conductive metal oxide, etc. For example, the common electrode CTE may include silver (Ag), an alloy containing silver, molybdenum (Mo), an alloy containing molybdenum, aluminum (Al), an alloy containing aluminum, aluminum nitride (AIN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), etc.

The emission layer EL may generate light by the voltage difference between the first voltage and the second voltage. Accordingly, the pixel electrode ADE, the emission layer EL, and the common electrode CTE may be defined as a light emitting diode.

A thin film encapsulation layer may be disposed on the common electrode CTE. The thin film encapsulation layer may prevent moisture and oxygen from penetrating from the outside. For example, the thin film encapsulation layer may have a structure in which the first inorganic layer IL1, the organic layer OL, and the second inorganic layer IL2 may be alternately stacked each other.

Referring again to FIG. 3, the window adhesive layer WADL may be disposed on the display panel PNL, and may overlap the first flat area PA1, the second flat area PA2, and the folding area FA. The window adhesive layer WADL may include an adhesive material such as pressure-sensitive adhesive (PSA), optically clear adhesive (OCA), or optically clear adhesive resin (OCR). The window adhesive layer WADL may contact the window WIN and may adhere the window WIN to the display panel PNL.

The window WIN may be disposed on the window adhesive layer WADL. The window WIN may protect the display panel PNL. For example, the window WIN may be made of transparent polyimide (colorless polyimide), ultra-thin tempered glass (UTG), polyethylene terephthalate (PET), polyimide (PI), polyethersulfone (PS), and polyacrylate (PAR), polyetherimide (PEI), polyethylene naphthalate (PEN), polyphenylene sulfide (PPS), polycarbonate (PC), etc.

The window protection layer PL may be disposed on the window WIN. The window protection layer PL may protect the window WIN. In an embodiment, the window protection layer PL may include a plastic film and a hard coating layer. For example, the plastic film may include transparent polyimide (colorless polyimide), polyethylene terephthalate (PET), polyimide (PI), polyethersulfone (PS), polyacrylate (PAR), polyetherimide (PEI), polyethylene naphthalate (PEN), polyphenylene sulfide (PPS), polycarbonate (PC), etc. The surface of the window protection layer PL may be treated to prevent fingerprints.

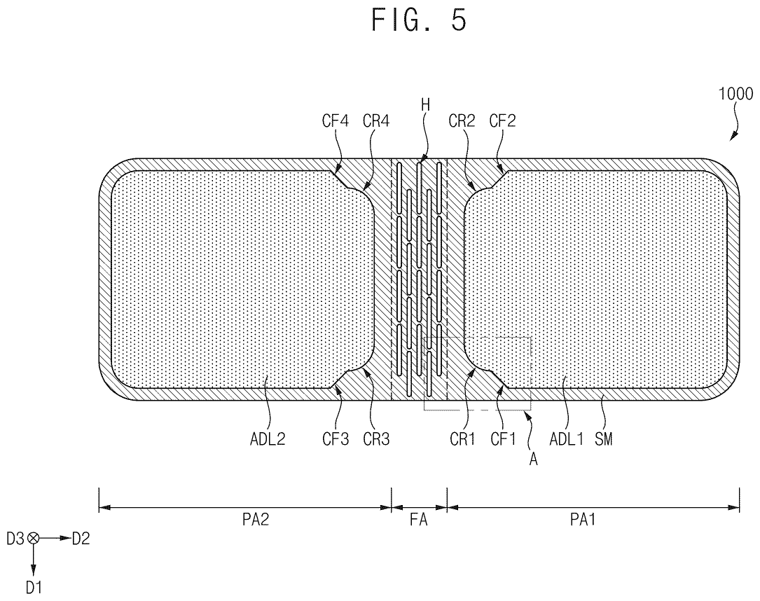

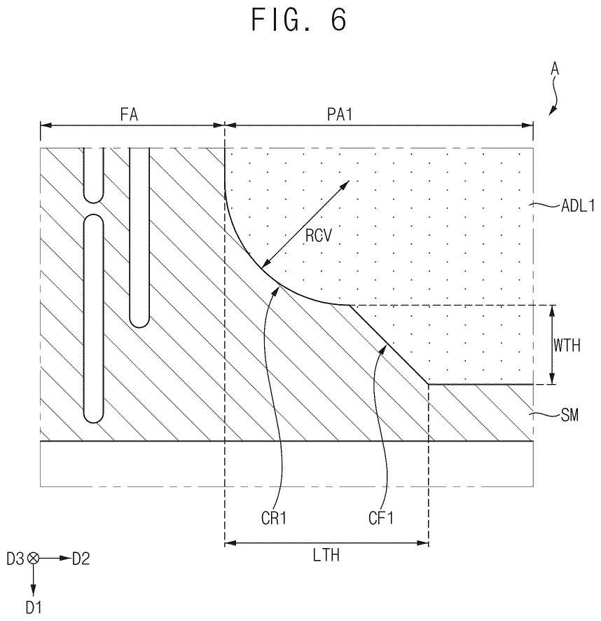

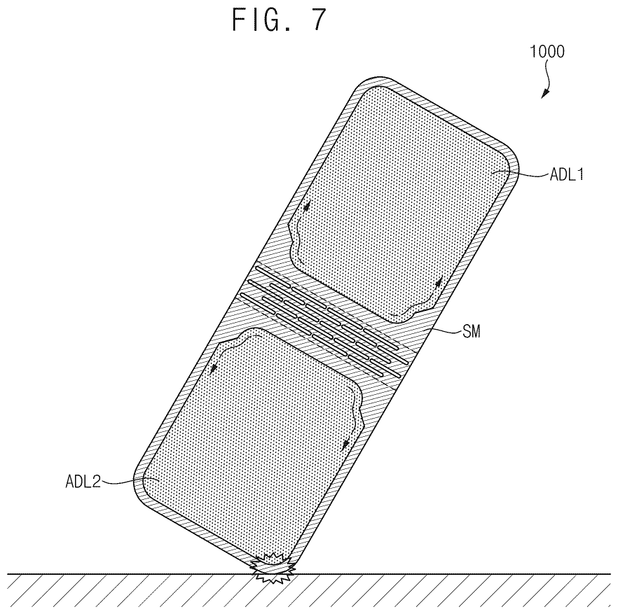

FIG. 5 is a rear view illustrating the foldable display device of FIG. 1. FIG. 6 is an enlarged view of area A of FIG. 5. FIG. 7 is a diagram illustrating a falling foldable display device of FIG. 5.

Referring to FIG. 5, the foldable display device 1000 may include the first adhesive layer ADL1 and the second adhesive layer ADL2. The first adhesive layer ADL1 may overlap the first flat area PA1, and the second adhesive layer ADL2 may overlap the second flat area PA2. The adhesive layer ADL may be removed from the folding area FA.

A planar shape of the first adhesive layer ADL1 may be substantially similar to a planar shape of the first flat area PA1. However, the first adhesive layer ADL1 may have a shape in which at least one corner adjacent to the folding area FA is processed.

In detail, the first adhesive layer ADL1 may include a first corner CR1, a first chamfer CF1, a second corner CR2, and a second chamfer CF2.

The first corner CR1 may be adjacent to the folding area FA, and a radius of curvature may be defined at the first corner CR1. The first chamfer CF1 may be connected to the first corner CR1.

The second corner CR2 may be adjacent to the folding area FA, and a radius of curvature may be defined at the second corner CR2. The second corner CR2 may be opposite to the first corner CR1. For example, a shape of the second corner CR2 may be symmetrical to a shape of the first corner CR1 with the second direction D2 as the axis of symmetry. The second chamfer CF2 may be connected to the second corner CR2. For example, a shape of the second chamfer CF2 may be symmetrical to a shape of the first chamfer CF1 with the second direction D2 as the axis of symmetry.

A planar shape of the second adhesive layer ADL2 may be substantially similar to a planar shape of the second flat area PA2. However, the second adhesive layer ADL2 may have a shape in which at least one corner adjacent to the folding area FA is processed.

In detail, the second adhesive layer ADL2 may include a third corner CR3, a third chamfer CF3, a fourth corner CR4, and a fourth chamfer CF4.

The third corner CR3 may be adjacent to the folding area FA, and a radius of curvature may be defined at the third corner CR3. A shape of the third corner CR3 may be symmetrical to the shape of the first corner CR1 with the first direction D1 as the axis of symmetry. The third chamfer CF3 may be connected to the third corner CR3. A shape of the third chamfer CF3 may be symmetrical to the shape of the first chamfer CF1 with the first direction D1 as the axis of symmetry.

The fourth corner CR4 may be adjacent to the folding area FA, and a radius of curvature may be defined at the fourth corner CR4. The fourth corner CR4 may be opposite to the third corner CR3. For example, a shape of the fourth corner CR4 may be symmetrical to the shape of the third corner CR3 with the second direction D2 as the axis of symmetry. The fourth chamfer CF4 may be connected to the fourth corner CR4. For example, as shape of the fourth chamfer CF4 may be symmetrical to the shape of the third chamfer CF3 with the second direction D2 as the axis of symmetry.

Referring to FIG. 6, a radius of curvature RCV may be defined at the first corner CR1. In an embodiment, the radius of curvature RCV may be in a range of about 2 mm to about 4 mm.

A maximum length LTH from the first corner CR1 to the first chamfer CF1 may be in a range of about 4 mm to about 6 mm, and a maximum width WTH of the first chamfer CF1 may be in a range of about 1 mm to about 3 mm.

However, the radius of curvature RCV, the maximum length LTH, and the maximum width WTH are not limited thereto. For example, the radius of curvature RCV, the maximum length LTH, and the maximum width WTH may be appropriately set according to a type of adhesive material constituting the first adhesive layer ADL1, a thickness of the first adhesive layer ADL1, a shape of the foldable display device 1000, a shape or strength of the support member SM, etc.

Referring to FIG. 7, in case that the foldable display device 1000 falls and collides with the ground, stress applied to the first adhesive layer ADL1 adjacent to the folding area FA may be distributed. In detail, by the shapes of the first corner CR1, the first chamfer CF1, the second corner CR2, and the second chamfer CF2 formed on the first adhesive layer ADL1, stress can be distributed rather than concentrated. Stress applied to the second adhesive layer ADL2 adjacent to the folding area FA may be distributed. Accordingly, the dropping performance of the foldable display device 1000 can be improved and reliability can be improved.

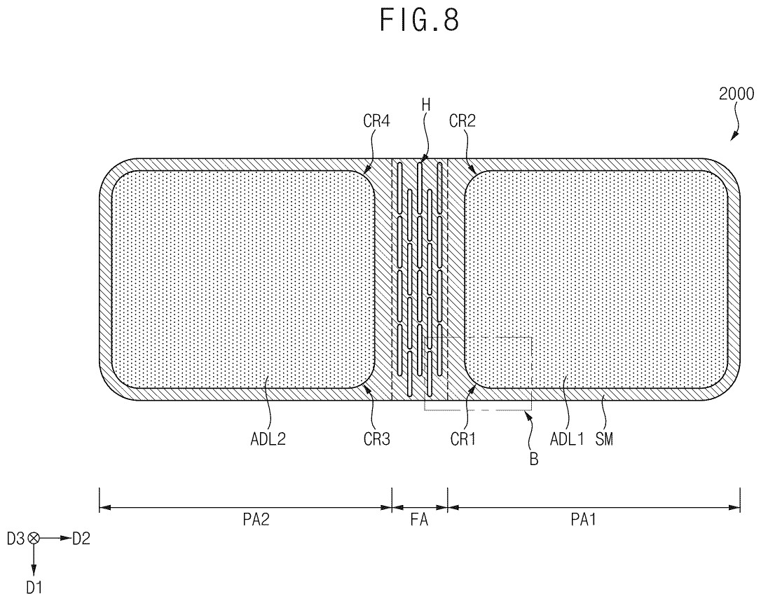

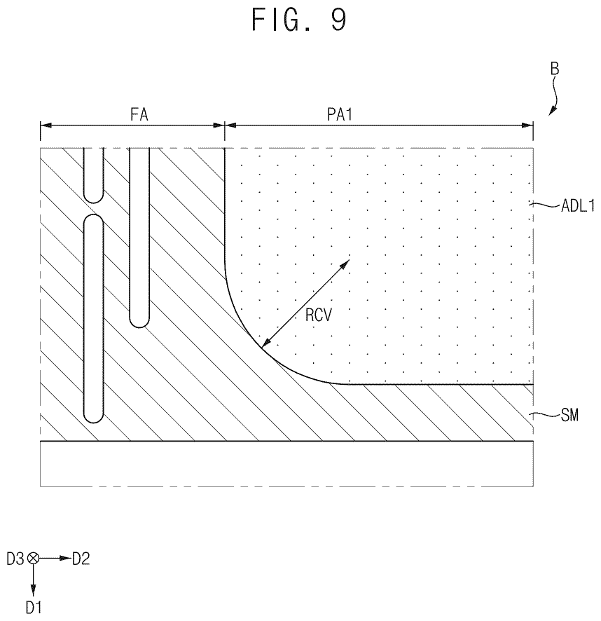

FIG. 8 is a rear view illustrating a foldable display device according to an embodiment. FIG. 9 is an enlarged view of area B of FIG. 8.

Referring to FIG. 8, a foldable display device 2000 according to an embodiment may include a support member SM, a first adhesive layer ADL1, and a second adhesive layer ADL2. However, the foldable display device 2000 may be substantially the same as the foldable display device 1000 described above with reference to FIGS. 1 to 7, except for the first adhesive layer ADL1 and the second adhesive layer ADL2.

The first adhesive layer ADL1 and the second adhesive layer ADL2 may contact the support member SM. The first adhesive layer ADL1 may overlap the first flat area PA1, and the second adhesive layer ADL2 may overlap the second flat area PA2. The adhesive layer ADL may be removed from the folding area FA.

The planar shape of the first adhesive layer ADL1 may be substantially similar to the planar shape of the first flat area PA1. However, the first adhesive layer ADL1 may have a shape in which at least one corner adjacent to the folding area FA is processed.

In detail, the first adhesive layer ADL1 may include a first corner CR1 and a second corner CR2.

The first corner CR1 may be adjacent to the folding area FA, and a radius of curvature may be defined at the first corner CR1.

The second corner CR2 may be adjacent to the folding area FA, and a radius of curvature may be defined at the second corner CR2. The second corner CR2 may be opposite to the first corner CR1. For example, the shape of the second corner CR2 may be symmetrical to the shape of the first corner CR1 with the second direction D2 as the axis of symmetry.

The planar shape of the second adhesive layer ADL2 may be substantially similar to the planar shape of the second flat area PA2. However, the second adhesive layer ADL2 may have a shape in which at least one corner adjacent to the folding area FA is processed.

In detail, the second adhesive layer ADL2 may include a third corner CR3 and a fourth corner CR4.

The third corner CR3 may be adjacent to the folding area FA, and a radius of curvature may be defined at the third corner CR3. The shape of the third corner CR3 may be symmetrical to the shape of the first corner CR1 with the first direction D1 as the axis of symmetry.

The fourth corner CR4 may be adjacent to the folding area FA, and a radius of curvature may be defined at the fourth corner CR4. The fourth corner CR4 may be opposite to the third corner CR3. For example, the shape of the fourth corner CR4 may be symmetrical to the shape of the third corner CR3 with the second direction D2 as the axis of symmetry.

Referring to FIG. 9, a radius of curvature RCV may be defined at the first corner CR1. In an embodiment, the radius of curvature RCV may be in a range of about 2 mm to about 4 mm.

However, the radius of curvature RCV is not limited thereto. For example, the radius of curvature RCV may be appropriately set according to a type of adhesive material constituting the first adhesive layer ADL1, a thickness of the first adhesive layer ADL1, a shape of the foldable display device 2000, a shape or strength of the support member SM, etc.

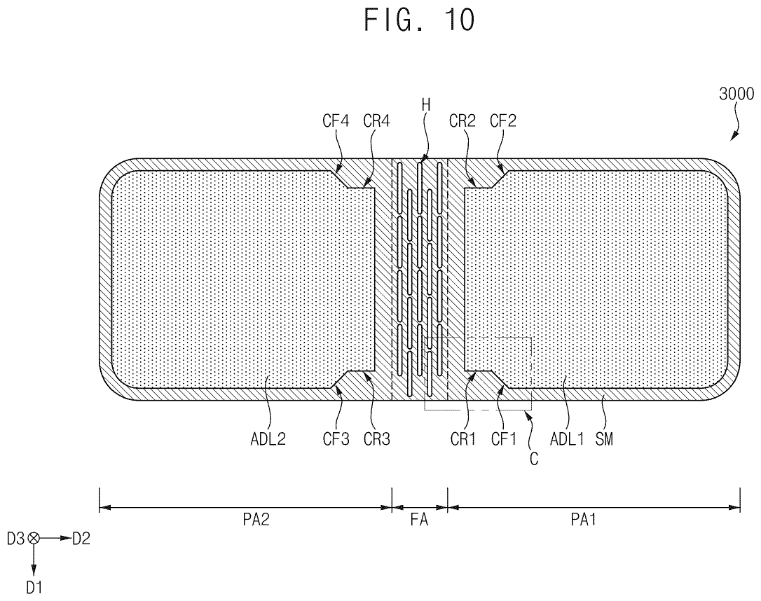

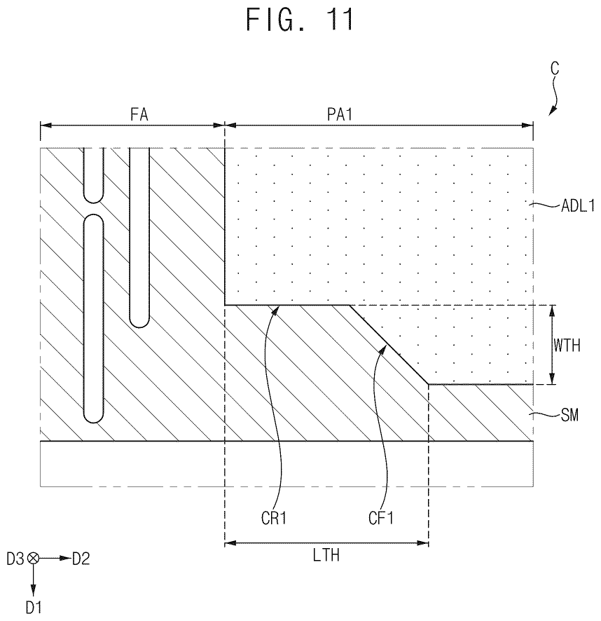

FIG. 10 is a rear view illustrating a foldable display device according to an embodiment. FIG. 11 is an enlarged view of area C of FIG. 10.

Referring to FIG. 10, a foldable display device 3000 according to an embodiment may include a support member SM, a first adhesive layer ADL1, and a second adhesive layer ADL2. However, the foldable display device 3000 may be substantially the same as the foldable display device 1000 described above with reference to FIGS. 1 to 7, except for the first adhesive layer ADL1 and the second adhesive layer ADL2.

The first adhesive layer ADL1 and the second adhesive layer ADL2 may contact the support member SM. The first adhesive layer ADL1 may overlap the first flat area PA1, and the second adhesive layer ADL2 may overlap the second flat area PA2.

The planar shape of the first adhesive layer ADL1 may be substantially similar to the planar shape of the first flat area PA1. However, the first adhesive layer ADL1 may have a shape in which at least one corner adjacent to the folding area FA is processed.

In detail, the first adhesive layer ADL1 may include a first corner CR1, a first chamfer CF1, a second corner CR2, and a second chamfer CF2.

The first corner CR1 may be adjacent to the folding area FA and may have a right-angled shape. The first chamfer CF1 may be connected to the first corner CR1.

The second corner CR2 may be adjacent to the folding area FA and may have a right-angled shape. The second corner CR2 may be opposite to the first corner CR1. For example, the shape of the second corner CR2 may be symmetrical to the shape of the first corner CR1 with the second direction D2 as the axis of symmetry. The second chamfer CF2 may be connected to the second corner CR2. For example, the shape of the second chamfer CF2 may be symmetrical to the shape of the first chamfer CF1 with the second direction D2 as the axis of symmetry.

The planar shape of the second adhesive layer ADL2 may be substantially similar to the planar shape of the second flat area PA2. However, the second adhesive layer ADL2 may have a shape in which at least one corner adjacent to the folding area FA is processed.

In detail, the second adhesive layer ADL2 may include a third corner CR3, a third chamfer CF3, a fourth corner CR4, and a fourth chamfer CF4.

The third corner CR3 may be adjacent to the folding area FA and may have a right-angled shape. The shape of the third corner CR3 may be symmetrical to the shape of the first corner CR1 with the first direction D1 as the axis of symmetry. The third chamfer CF3 may be connected to the third corner CR3. The shape of the third chamfer CF3 may be symmetrical to the shape of the first chamfer CF1 with the first direction D1 as the axis of symmetry.

The fourth corner CR4 may be adjacent to the folding area FA and may have a right-angled shape. The fourth corner CR4 may be opposite to the third corner CR3. For example, the shape of the fourth corner CR4 may be symmetrical to the shape of the third corner CR3 with the second direction D2 as the axis of symmetry. The fourth chamfer CF4 may be connected to the fourth corner CR4. For example, the shape of the fourth chamfer CF4 may be symmetrical to the shape of the third chamfer CF3 with the second direction D2 as the axis of symmetry.

Referring to FIG. 11, a maximum length LTH from the first corner CR1 to the first chamfer CF1 may be in a range of about 4 mm to about 6 mm, and a maximum width WTH of the first chamfer CF1 may be in a range of about 1 mm to about 3 mm.

However, the maximum length LTH and the maximum width WTH is not limited thereto. For example, the maximum length LTH and the maximum width WTH may be appropriately set according to a type of adhesive material constituting the first adhesive layer ADL1, a thickness of the first adhesive layer ADL1, a shape of the foldable display device 3000, a shape or strength of the support member SM, etc.

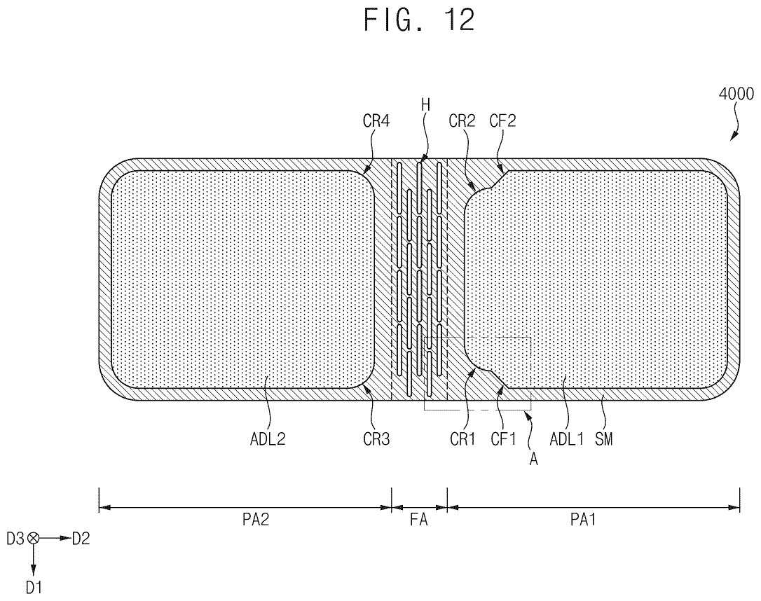

FIG. 12 is a rear view illustrating a foldable display device according to an embodiment.

Referring to FIG. 12, a foldable display device 4000 according to an embodiment may include a support member SM, a first adhesive layer ADL1, and a second adhesive layer ADL2. However, the foldable display device 4000 may be substantially the same as the foldable display device 1000 described above with reference to FIGS. 1 to 7, except for the first adhesive layer ADL1 and the second adhesive layer ADL2.

The first adhesive layer ADL1 and the second adhesive layer ADL2 may contact the support member SM. The first adhesive layer ADL1 may overlap the first flat area PA1, and the second adhesive layer ADL2 may overlap the second flat area PA2.

The planar shape of the first adhesive layer ADL1 may be substantially similar to the planar shape of the first flat area PA1. However, the first adhesive layer ADL1 may have a shape in which at least one corner adjacent to the folding area FA is processed.

In an embodiment, the shape of the first adhesive layer ADL1 may be substantially the same as the shape of the first adhesive layer ADLI described with reference to FIG. 5. In detail, the first adhesive layer ADL1 may include a first corner CR1, a first chamfer CF1, a second corner CR2, and a second chamfer CF2.

The first corner CR1 may be adjacent to the folding area FA, and a radius of curvature may be defined at the first corner CR1. The first chamfer CF1 may be connected to the first corner CR1.

The second corner CR2 may be adjacent to the folding area FA, and a radius of curvature may be defined at the second corner CR2. The second corner CR2 may be opposite to the first corner CR1. For example, the shape of the second corner CR2 may be symmetrical to the shape of the first corner CR1 with the second direction D2 as the axis of symmetry. The second chamfer CF2 may be connected to the second corner CR2. For example, the shape of the second chamfer CF2 may be symmetrical to the shape of the first chamfer CF1 with the second direction D2 as the axis of symmetry.

In an embodiment, the shape of the second adhesive layer ADL2 may be substantially the same as the shape of the second adhesive layer ADL2 described with reference to FIG. 8. In detail, the second adhesive layer ADL2 may include a third corner CR3 and a fourth corner CR4.

The third corner CR3 may be adjacent to the folding area FA, and a radius of curvature may be defined at the third corner CR3. The shape of the third corner CR3 may not be symmetrical to the shape of the first corner CR1 with respect to the first direction D1 as the axis of symmetry.

The fourth corner CR4 may be adjacent to the folding area FA, and a radius of curvature may be defined at the fourth corner CR4. The fourth corner CR4 may be opposite to the third corner CR3. For example, the shape of the fourth corner CR4 may be symmetrical to the shape of the third corner CR3 with the second direction D2 as the axis of symmetry.

In an embodiment, the shape of the first adhesive layer ADL1 and the shape of the second adhesive layer ADL2 may not be symmetrical to each other. For example, as shown in FIG. 12, the first and second chamfers CF1 and CF2 may be formed in the first adhesive layer ADL1, and any chamfer may not form in the second adhesive layer ADL2.

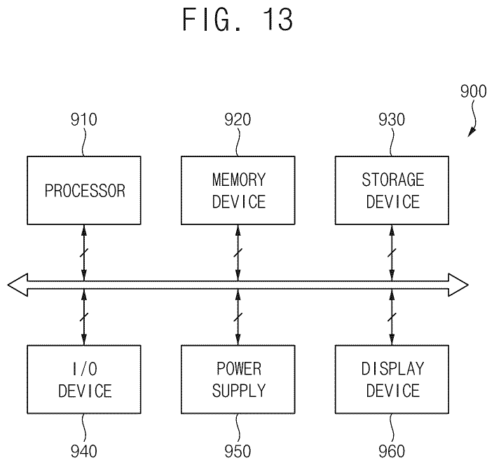

FIG. 13 is a block diagram illustrating an electronic device according to an embodiment.

Referring to FIG. 13, in an embodiment, an electronic device 900 may include a processor 910, a memory device 920, a storage device 930, an input/output (“I/O”) device 940, a power supply 950, and a display device 960. Here, the display device 960 may correspond to the foldable display device 1000 of FIG. 1, the foldable display device 2000 of FIG. 8, the foldable display device 3000 of FIG. 10, or the foldable display device 4000 of FIG. 12. The electronic device 900 may further include a plurality of ports for communicating with a video card, a sound card, a memory card, a universal serial bus (“USB”) device, or the like. In an embodiment, the electronic device 900 may be implemented as a television. In another embodiment, the electronic device 900 may be implemented as a smart phone. However, embodiments are not limited thereto, in another embodiment, the electronic device 900 may be implemented as a cellular phone, a video phone, a smart pad, a smart watch, a tablet personal computer (“PC”), a car navigation system, a computer monitor, a laptop, a head disposed (e.g., mounted) display (“HMD”), or the like.

The processor 910 may perform various computing functions. In an embodiment, the processor 910 may be a microprocessor, a central processing unit (“CPU”), an application processor (“AP”), or the like. The processor 910 may be coupled to other components via an address bus, a control bus, a data bus, or the like. In an embodiment, the processor 910 may be coupled to an extended bus such as a peripheral component interconnection (“PCI”) bus.

The memory device 920 may store data for operations of the electronic device 900. In an embodiment, the memory device 920 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 930 may include a solid state drive (“SSD”) device, a hard disk drive (“HDD”) device, a CD-ROM device, or the like. In an embodiment, the I/O device 940 may include an input device such as a keyboard, a keypad, a mouse device, a touchpad, a touch-screen, or the like, and an output device such as a printer, a speaker, or the like.

The power supply 950 may provide power for operations of the electronic device 900. The power supply 950 may provide power to the display device 960. The display device 960 may be coupled to other components via the buses or other communication links. In an embodiment, the display device 960 may be included in the I/O device 940.

Although embodiments and implementations have been described herein, other embodiments and modifications will be apparent from this description. Accordingly, the disclosure is not limited to such embodiments, but rather to the broader scope of the appended claims and various modifications and equivalent arrangements as would be apparent to a person of ordinary skill in the art.

What is claimed is:

1. A foldable display device comprising:
a support member divided into a folding area and at least one flat area adjacent to the folding area;
at least one adhesive layer disposed on the support member, overlapping the at least one flat area, and including at least one corner having a radius of curvature, the at least one corner being adjacent to the folding area; and
a display panel disposed on the at least one adhesive layer.

2. The foldable display device of claim 1, wherein the radius of curvature is in a range of about 2 mm to about 4 mm.

3. The foldable display device of claim 1, wherein the at least one adhesive layer includes:
a first corner adjacent to the folding area; and
a second corner adjacent to the folding area and opposite to the first corner,
wherein the radius of curvature is defined at each of the first corner and the second corner, and
a shape of the second corner is substantially symmetrical to a shape of the first corner.

4. The foldable display device of claim 1, wherein
the at least one flat area includes a first flat area and a second flat area facing each other with the folding area disposed between the first flat area and the second flat area,
the at least one adhesive layer includes a first adhesive layer overlapping the first flat area and a second adhesive layer overlapping the second flat area, and
a shape of a corner included in the second adhesive layer is substantially symmetrical to a shape of a corner included in the first adhesive layer.

5. The foldable display device of claim 1, wherein the at least one adhesive layer further includes a chamfer connected to the corner.

6. The foldable display device of claim 5, wherein
the at least one adhesive layer includes:
a first corner adjacent to the folding area;
a first chamfer connected to the first corner;
a second corner adjacent to the folding area and opposite to the first corner; and
a second chamfer connected to the second corner,
the radius of curvature is defined at each of the first corner and the second corner,
a shape of the second corner is substantially symmetrical to a shape of the first corner, and
a shape of the second chamfer is substantially symmetrical to a shape of the first chamfer.

7. The foldable display device of claim 5, wherein
the at least one flat area includes a first flat area and a second flat area facing each other with the folding area disposed between the first flat area and the second flat area,
the at least one adhesive layer includes a first adhesive layer overlapping the first flat area and a second adhesive layer overlapping the second flat area,
a shape of a corner included in the second adhesive layer is substantially symmetrical to a shape of a corner included in the first adhesive layer, and
a shape of a chamfer included in the second adhesive layer is substantially symmetrical to a shape of a chamfer included in the first adhesive layer.

8. The foldable display device of claim 5, wherein a maximum length from the corner to the chamfer is in a range of about 4 mm to about 6 mm.

9. The foldable display device of claim 5, wherein a maximum width of the chamfer is in a range of about 1 mm to about 3 mm.

10. The foldable display device of claim 5, wherein
the at least one flat area includes a first flat area and a second flat area facing each other with the folding area disposed between the first flat area and the second flat area,
the at least one adhesive layer includes a first adhesive layer overlapping the first flat area and a second adhesive layer overlapping the second flat area,
the first adhesive layer includes the corner and the chamfer, and
the second adhesive layer includes a corner with radius of curvature.

11. The foldable display device of claim 1, wherein holes overlapping the folding area are included in the support member.

12. The foldable display device of claim 1, further comprising:
a protective layer disposed between the at least one adhesive layer and the display panel; and
a panel adhesive layer disposed between the protective layer and the display panel, and overlapping the folding area and the at least one flat area.

13. The foldable display device of claim 1, wherein the at least one adhesive layer does not overlap the folding area.

14. The foldable display device of claim 1, wherein the display panel includes:
an active pattern disposed on a substrate;
a gate electrode disposed on the active pattern;
a connection electrode disposed on the gate electrode and electrically connected to the active pattern;
a pixel electrode disposed on the connection electrode and electrically connected to the connection electrode;
an emission layer disposed on the pixel electrode; and
a common electrode disposed on the emission layer.

15. A foldable display device comprising:
a support member divided into a folding area and at least one flat area adjacent to the folding area;
at least one adhesive layer disposed on the support member, overlapping the at least one flat area, and including at least one chamfer adjacent to the folding area; and
a display panel disposed on the at least one adhesive layer.

16. The foldable display device of claim 15, wherein the at least one adhesive layer includes:
a first chamfer adjacent to the folding area; and
a second chamfer adjacent to the folding area and opposite to the first chamfer, and a shape of the second chamfer is substantially symmetrical to a shape of the first chamfer.

17. The foldable display device of claim 15, wherein
the at least one flat area includes a first flat area and a second flat area facing each other with the folding area disposed between the first flat area and the second flat area,
the at least one adhesive layer includes a first adhesive layer overlapping the first flat area and a second adhesive layer overlapping the second flat area, and
a shape of a chamfer included in the second adhesive layer is substantially symmetrical to a shape of a chamfer included in the first adhesive layer.

18. The foldable display device of claim 15, wherein a maximum width of the chamfer is in a range of about 1 mm to about 3 mm.

19. An electronic device comprising:
a foldable display device; and
a power supply that provides power to the foldable display device,
wherein the foldable display device comprises:
a support member divided into a folding area and at least one flat area adjacent to the folding area;
at least one adhesive layer disposed on the support member, overlapping the at least one flat area, and including at least one corner having a radius of curvature, the at least one corner being adjacent to the folding area; and
a display panel disposed on the at least one adhesive layer.
